(19) United States
(12) Patent Application Publication
(10) Pub. No.: US 2015/0189735 A1
(43) Pub. Date: Jul. 2, 2015

(54) RIGID FLEXIBLE PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Kyung Chul Yu, Suwon-si (KR); Ha II Kim, Suwon-si (KR); Young Man Kim, Suwon-si (KR); Dong Gi An, Suwon-si (KR)

(73) Assignee: SAMSUNG ELECTRO-MECHANICS CO., LTD., Suwon-Si (KR)

(21) Appl. No.: 14/249,124

(22) Filed: Apr. 9, 2014

(30) Foreign Application Priority Data
Dec. 26, 2013 (KR) 10-2013-0164194

(51) Int. Cl. H05K 1/02; H05K 1/03; H05K 3/10

(52) U.S. Cl. CPC H05K 1/028; H05K 3/10; H05K 1/0393

(57) ABSTRACT

Disclosed herein are a rigid flexible printed circuit board and a method of manufacturing the same. The rigid flexible printed circuit board includes: a flexible substrate having a flexible region and a plurality of rigid regions; a first insulating layer formed in the rigid regions and extended from the rigid regions to cover a portion of the flexible region; and a plurality of build-up layers formed in the first insulating layer of the rigid regions and including a build-up insulating layer and a circuit pattern, wherein at least one of the plurality of build-up layers has a thickness different from those of the other build-up layers.

### CROSS REFERENCE TO RELATED APPLICATION

This application claims the benefit of Korean Patent Application No. 10-2013-0164194, filed on Dec. 26, 2013, entitled “Rigid Flexible Printed Circuit Board and Method of Manufacturing the Same”, which is hereby incorporated by reference in its entirety into this application.

### BACKGROUND OF THE INVENTION

1. Technical Field

The present invention relates to a rigid flexible printed circuit board and a method of manufacturing the same.

2. Description of the Related Art

Recently, importance of miniaturization, thinness, and an appearance design of electronic components has increased. In order to implement an electronic product satisfying these requirements, the importance of a printed circuit board inserted into the electronic product has been emphasized. In accordance with the miniaturization and the thinness of the electronic product, a rigid flexible printed circuit board has been used as a board inserted into the electronic product. The rigid flexible printed circuit board has been divided into a rigid part in which a sensor and a component are mounted and a flexible part which is a bent part and has been efficiently used, in order to be efficiently disposed in a narrow space.

### PRIOR ART DOCUMENT

### Patent Document

(Patent Document 1) US Patent Application Publication No. 2008-0014768

### SUMMARY OF THE INVENTION

The present invention has been made in an effort to provide a rigid flexible printed circuit board in which build-up layers having various numbers are formed, and a method of manufacturing the same.

Further, the present invention has been made in an effort to provide a rigid flexible printed circuit board capable of preventing damage to an internal protective layer exposed in a flexible region, and a method of manufacturing the same.

According to a preferred embodiment of the present invention, there is provided a rigid flexible printed circuit board including: a flexible substrate having a flexible region and a plurality of rigid regions; a first insulating layer formed in the rigid regions and extended from the rigid regions to cover a portion of the flexible region; and a plurality of build-up layers formed in the first insulating layer of the rigid regions and including a build-up insulating layer and a circuit pattern, wherein at least one of the plurality of build-up layers has a thickness different from those of the other build-up layers.

The rigid flexible printed circuit board may further include protective layers formed on the build-up layers.

The protective layer may be formed of a solder resist or a coverlay.

A protective layer of a build-up layer having the thickest thickness among the plurality of build-up layers may be formed of a solder resist, and protective layers of the other build-up layers may be formed of a coverlay.

The first insulating layer and the build-up layer may be formed on both surfaces of the flexible substrate.

The flexible substrate may include a flexible insulating layer, an internal circuit pattern formed on one surface or both surfaces of the flexible insulating layer, and an internal protective layer formed on the internal circuit pattern.

The internal protective layer may be formed of a coverlay.

According to another preferred embodiment of the present invention, there is provided a method of manufacturing a rigid flexible printed circuit board, including: preparing a flexible substrate having a flexible region and a plurality of rigid regions; forming a first insulating layer in the rigid regions so as to be extended from the rigid regions to cover a portion of the flexible region; forming a first build-up layer at an upper portion of the flexible region and on the first insulating layer, the first build-up layer including a first build-up insulating layer and a first circuit pattern; forming a boundary layer on a first build-up layer of at least one of the plurality of rigid regions; forming a second build-up layer on the first build-up layer and the boundary layer, the second build-up layer including a second build-up insulating layer and a second circuit pattern; removing the first build-up layer and the second build-up layer of the flexible region; and removing the second build-up layer formed on the boundary layer.

The forming of the first build-up layer may include forming an etching stop pattern in the flexible region.

The etching stop pattern may be formed simultaneously with the first circuit pattern.

The removing of the first build-up layer and the second build-up layer may include: removing the first build-up layer and the second build-up layer formed on the first insulating layer formed in the flexible region using a laser drill; wet-etching the etching stop pattern exposed by removing the first build-up layer and the second build-up layer; removing the first build-up insulating layer by wet-etching the etching stop pattern using the laser drill; and separating and removing the first build-up insulating layer, the etching stop pattern, and the first build-up layer, and the second build-up layer formed at the upper portion of the flexible region.

In the forming of the boundary layer, the boundary layer may include a protective layer positioned on an upper surface of the first build-up layer and a release layer formed on the protective layer.

The protective layer may be formed of a coverlay.

In the removing of the second build-up layer formed on the boundary layer, the protective layer and the release layer of the boundary layer may be separated from each other, such that the release layer and the second build-up layer are removed.

In the forming of the boundary layer, the boundary layer may further include an adhesive layer interposed between the protective layer and the release layer, and in the removing of the second build-up layer formed on the boundary layer, the protective layer and the adhesive layer of the boundary layer may be separated from each other, such that the adhesive layer, the release layer, and the second build-up layer are removed.

The method of manufacturing a rigid flexible printed circuit board may further include, after the forming of the second build-up layer or after the removing of the second build-up layer formed on the boundary layer, forming an external protective layer on the second build-up layer of the rigid region.

In the forming of the external protective layer, the external protective layer may be formed of solder ink or a coverlay.

In the forming of the first insulating layer, the first insulating layer may be formed on both surfaces of the flexible substrate.

The flexible substrate may include a flexible insulating layer, an internal circuit pattern formed on one surface or both surfaces of the flexible insulating layer, and an internal protective layer formed on the internal circuit pattern.

The internal protective layer may be formed of a coverlay.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an illustrative view showing a rigid flexible printed circuit board according to a preferred embodiment of the present invention; and

FIGS. 2 to 15 are illustrative views showing a method of manufacturing a rigid flexible printed circuit board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

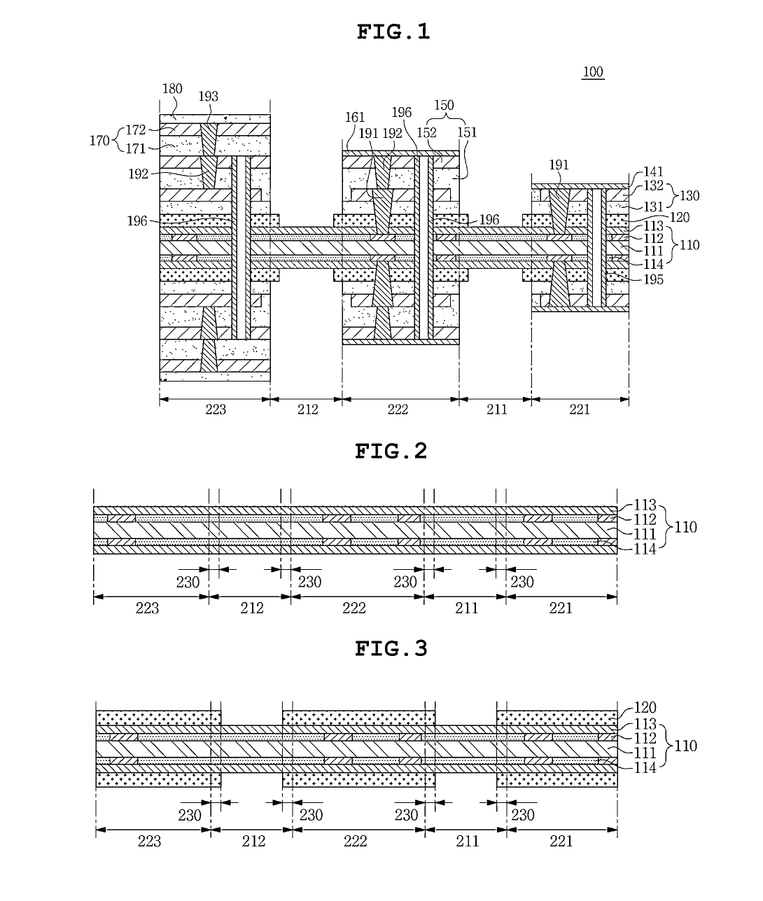

FIG. 1 is an illustrative view showing a rigid flexible printed circuit board according to a preferred embodiment of the present invention.

Referring to FIG. 1, a rigid flexible printed circuit board 100 may be configured to include a flexible substrate 110, a first insulating layer 120, first to third build-up layers 130 to 170, a first protective layer 141, a second protective layer 161, and an external protective layer 180.

The flexible substrate 110 according to a preferred embodiment of the present invention may include a flexible insulating layer 111, an internal circuit pattern 112, an internal protective layer 113, and an internal adhesive layer 114. The flexible insulating layer 111 may be formed of a flexible insulating film. For example, the flexible insulating layer 111 may be formed of polyimide (PI).

The flexible insulating layer 111 may have the internal circuit pattern 112 formed thereon. The case in which the internal circuit patterns 112 are formed on both surfaces of the flexible insulating layer 111 has been shown in FIG. 2. However, the internal circuit patterns 112 are not limited to being formed on both surfaces of the flexible insulating layer 111. For example, the internal circuit pattern 112 may be formed on only one surface of the flexible insulating layer 111. The internal circuit pattern 112 may be formed of a conductive metal that is used in a field of circuit board. For example, the internal circuit pattern 112 may be formed of copper.

The internal circuit pattern 112 may have the internal protective layer 113 formed thereon. The internal protective layer 113 may be formed in order to protect the internal circuit pattern 112 from an external environment. For example, the internal protective layer 113 may be formed of a coverlay.

The internal adhesive layer 114 may be formed between the internal circuit pattern 112 and the internal protective layer 113. The internal adhesive layer 114 may improve adhesion between the internal circuit pattern 112, the flexible insulating layer 111, and the internal protective layer 113.

The flexible substrate 110 formed as described above may be divided into a flexible region and a rigid region. The flexible region, which is a flexible part of the rigid flexible printed circuit board 100, may be bent. The rigid region may be positioned at one side or both sides of the flexible region and may have a build-up layer formed thereon. In a preferred embodiment of the present invention, the flexible substrate 110 may include a first flexible region 211, a second flexible region 212, and first to third rigid regions 221 to 223. Although the case in which the flexible substrate 110 includes two flexible regions and three rigid regions has been described in a preferred embodiment of the present invention, this is only an example. That is, the number of flexible regions and rigid regions may be changed by selection of those skilled in the art.

In addition, although the case in which the flexible substrate 110 includes one flexible insulating layer and the internal circuit pattern has been described in a preferred embodiment of the present invention, the present invention is not limited thereto. That is, the flexible substrate 110 may include a plurality of flexible insulating layers and the internal circuit pattern depending on selection of those skilled in the art.

The first insulating layer 120 according to a preferred embodiment of the present invention may be formed on the internal protective layer 113 of the first to third rigid regions 221 to 223. In addition, the first insulating layer 120 may be extended from the first to third rigid regions 221 to 223 to cover portions of the first and second flexible regions 211 and 212. A portion of the internal protective layer 113 formed in the first and second flexible regions 211 and 212 may be exposed by the first insulating layer 120 formed as described above.

The first insulating layer 120 according to a preferred embodiment of the present invention may be formed of a thermosetting insulating resin. For example, the first insulating layer 120 may be formed of prepreg.

The first build-up layer 130 according to a preferred embodiment of the present may be formed on the first insulating layer 120 and be formed in the first to third rigid regions 221 to 223. For example, the first build-up layer 130 may include a first build-up insulating layer 131 and a first circuit pattern 132. The first build-up insulating layer 131 may be formed on an upper surface of the first insulating layer 120. Here, since the first build-up insulating layer 131 is formed in only the first to third rigid regions 221 to 223, it may expose the first insulating layer 120 formed on the first and second flexible regions 211 and 212. That is, the first insulating layer 120 and the first build-up insulating layer 131 may be formed in a step structure. The first circuit pattern 132 may be formed on the first insulating layer 120.

The second build-up layer 150 according to a preferred embodiment of the present invention may be formed on the first build-up layer 130 formed in the second and third rigid regions 222 and 223. For example, the second build-up layer 150 may include a second build-up insulating layer 151 and a second circuit pattern 152. The second build-up insulating layer 151 may enclose the first circuit pattern 132 formed in the second and third rigid regions 222 and 223. The second circuit pattern 152 may be formed on the second build-up insulating layer 151.

The third build-up layer 170 according to a preferred embodiment of the present invention may be formed on the second build-up layer 150 formed in the third rigid region 223. For example, the third build-up layer 170 may include a third build-up insulating layer 171 and a third circuit pattern 172. The third build-up insulating layer 171 may enclose the second circuit pattern 152 formed in the third rigid region 223. The third circuit pattern 172 may be formed on the third build-up insulating layer 171.

As described above, the rigid flexible printed circuit board 100 according to a preferred embodiment of the present invention may have various layers. That is, the rigid flexible printed circuit board 100 according to a preferred embodiment of the present invention may have various thicknesses.

The first protective layer 141 according to a preferred embodiment of the present invention may be formed on the first circuit pattern 132 of the first rigid region 221. The second protective layer 161 may be formed on the second circuit pattern 152 of the second rigid region 222. The external protective layer 180 may be formed on the third circuit pattern 172 of the third rigid region 223. The first protective layer 141, the second protective layer 161, and the external protective layer 180 may be formed in order to protect the first to third circuit pattern 132 to 172 from an external environment or material such as a solder, or the like. For example, the first protective layer 141, the second protective layer 161, and the external protective layer 180 may be formed of a liquid or film type of solder resist. Alternatively, the first protective layer 141, the second protective layer 161, and the external protective layer 180 may be formed of a coverlay. However, the first protective layer 141, the second protective layer 161, and the external protective layer 180 are not limited to being formed of the above-mentioned material, may be formed of a material selected among multiple materials protecting a circuit pattern in a field of circuit board. In a preferred embodiment of the present invention, the first and second protective layers 141 and 161 may be formed of a coverlay, and the external protective layer 180 may be formed of SR ink.

Although the case in which the first protective layer 141 is formed in the first rigid region 221, the second protective layer 161 is formed in the second rigid region 222, and the external protective layer 180 is formed in the third rigid region 223 has been described by way of example in a preferred embodiment of the present invention, the present invention is not limited to this structure. For example, the external protective layer 180 may be formed on the first and second protective layers 141 and 161 as well as in the third rigid region 223. In addition, the external protective layer 180 may be formed in the first and second rigid regions 221 and 222 instead of being formed on the first and second protective layers 141 and 161.

In addition, according to a preferred embodiment of the present invention, the rigid flexible printed circuit board 100 may include a via and a penetration via. For example, the rigid flexible printed circuit board 100 may further include first to third vias 191 to 193 and first and second penetration vias 195 and 196 formed therein.

The first via 191 may penetrate through the first insulating layer 120 and the first build-up insulating layer 131 to electrically connect the internal circuit pattern 112 and the first circuit pattern 132 to each other.

The second via 192 may penetrate through the second build-up insulating layer 151 to electrically connect the first circuit pattern 132 and the second circuit pattern 152 to each other.

The third via 193 may penetrate through the third build-up insulating layer 171 to electrically connect the second circuit pattern 152 and the third circuit pattern 172 to each other.

The first penetration via 195 may electrically connect the first circuit patterns 132 formed above and below the flexible substrate 110, respectively, to each other.

The second penetration via 196 may electrically connect the second circuit patterns 152 formed above and below the flexible substrate 110, respectively, to each other.

According to a preferred embodiment of the present invention, the first via 191 and the first penetration via 195 may be formed in the first rigid region 221. In addition, the first and second vias 191 and 192 and the second penetration via 196 may be formed in the second rigid region 222. Further, the second and third vias 192 and 193 and the second penetration via 196 may be formed in the third rigid region 223.

The positions and the numbers of vias and penetration vias as described above are only an example of the present invention and are not limited thereto. That is, structures, the numbers, and positions of vias and penetration vias may be changed by selection of those skilled in the art.

FIGS. 2 to 15 are illustrative views showing a method of manufacturing a rigid flexible printed circuit board according to a preferred embodiment of the present invention.

Referring to FIG. 2, a flexible substrate 110 may be prepared.

In a preferred embodiment of the present invention, the flexible substrate 110 may include a flexible insulating layer 111, an internal circuit pattern 112, an internal protective layer 113, and an internal adhesive layer 114. The flexible insulating layer 111 may be formed of a flexible insulating film. For example, the flexible insulating layer 111 may be formed of polyimide (PI).

The flexible insulating layer 111 may have the internal circuit pattern 112 formed thereon. The case in which the internal circuit patterns 112 are formed on both surfaces of the flexible insulating layer 111 has been shown in FIG. 2. However, the internal circuit patterns 112 are not limited to being formed on both surfaces of the flexible insulating layer 111. For example, the internal circuit pattern 112 may be formed on only one surface of the flexible insulating layer 111. The internal circuit pattern 112 may be formed of a conductive metal that is used in a field of circuit board. For example, the internal circuit pattern 112 may be formed of copper. The flexible insulating layer 111 and the internal circuit pattern 112 according to a preferred embodiment of the present invention may be formed of a double-sided flexible copper clad laminate (FCCL). The double-sided FCCL has a structure in which copper foils are formed on both surfaces of a flexible insulating film. For example, copper foils of the double-sided FCCL may be patterned to form the internal circuit pattern 112. However, this is only an example, and the present invention is not limited thereto.

The internal circuit pattern 112 may have the internal protective layer 113 formed thereon. The internal protective layer 113 may be formed in order to protect the internal circuit pattern 112 from an external environment. For example, the internal protective layer 113 may be formed of a coverlay.

The internal adhesive layer 114 may be formed between the internal circuit pattern 112 and the internal protective layer 113. The internal adhesive layer 114 may improve adhesion between the internal circuit pattern 112, the flexible insulating layer 111, and the internal protective layer 113.

The flexible substrate 110 formed as described above may be divided into a flexible region and a rigid region. The flexible region may be flexibly bent. The rigid region may be positioned at one side or both sides of the flexible region and may have a build-up layer to be formed thereon later. In a preferred embodiment of the present invention, the flexible substrate 110 may include a first flexible region 211, a second flexible region 212, and first to third rigid regions 221 to 223. Although the case in which the flexible substrate 110 includes two flexible regions and three rigid regions has been described in a preferred embodiment of the present invention, this is only an example. That is, the number of flexible regions and rigid regions may be changed by selection of those skilled in the art.

In addition, although the case in which the flexible substrate 110 includes one flexible insulating layer and the internal circuit pattern has been described in a preferred embodiment of the present invention, the present invention is not limited thereto. That is, the flexible substrate 110 may include a plurality of flexible insulating layers and the internal circuit pattern depending on selection of those skilled in the art.

Referring to FIG. 3, a first insulating layer 120 may be formed on the flexible substrate 110.

In a preferred embodiment of the present invention, the first insulating layer 120 may be formed in the first to third rigid regions 221 to 223. In addition, the first insulating layer 120 may be extended from the first to third rigid regions 221 to 223 to cover portions of the first and second flexible regions 211 and 212. A portion of the internal protective layer 113 formed in the first and second flexible regions 211 and 212 may be exposed by the first insulating layer 120 formed as described above.

The first insulating layer 120 according to a preferred embodiment of the present invention may be formed of a thermosetting insulating resin. For example, the first insulating layer 120 may be formed of prepreg.

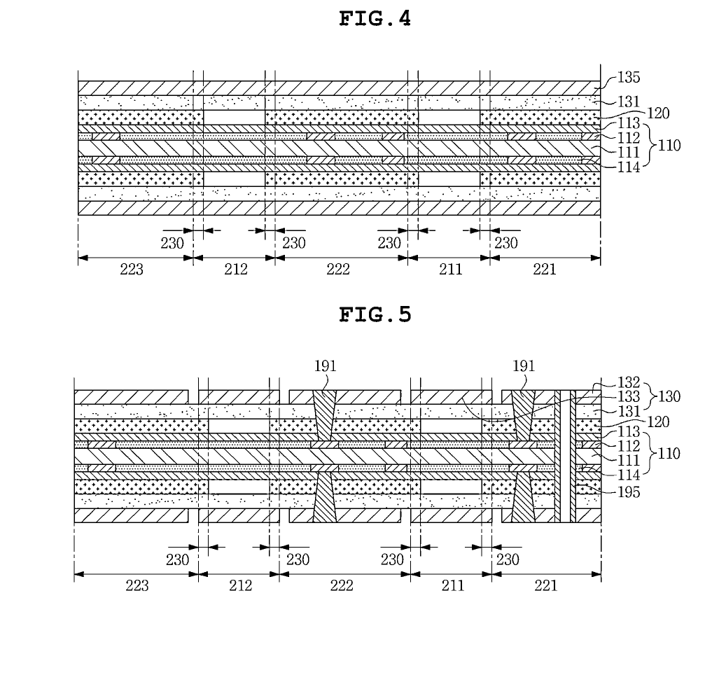

Referring to FIG. 4, a first build-up insulating layer 131 and a first metal layer 135 may be formed on the first insulating layer 120.

In a preferred embodiment of the present invention, the first build-up insulating layer 131 may be positioned above the flexible substrate 110 and be formed on an upper surface of the first insulating layer 120. The first metal layer 135 may be formed on an upper surface of the first build-up insulating layer 131. For example, the first build-up insulating layer 131 and the first metal layer 135 may be formed using a single-sided FCCL. The single-sided FCCL has a structure in which a copper foil is formed on one surface of a flexible insulating film. That is, the flexible insulating film of the single-sided FCCL may become the first build-up insulating layer 131, and the copper foil may become the first metal layer 135.

Referring to FIG. 5, a first circuit pattern 132 and a first etching stop pattern 133 may be formed.

According to a preferred embodiment of the present invention, the first circuit pattern 132 may be formed by patterning the first metal layer 135. The first circuit pattern 132 may be formed in at least one of the first to third rigid regions 221 to 223. In a preferred embodiment of the present invention, the first circuit pattern 132 may be formed in the first to third rigid regions 221 to 223.

In addition, the first etching stop pattern 133 may be formed. The first etching stop pattern 133 may be formed in order to protect the flexible substrate 110 positioned thereunder at the time of performing etching later using a laser drill. In a preferred embodiment of the present invention, the first etching stop pattern 133 may be formed in the first and second flexible regions 211 and 212. Here, the first insulating layer 120 may cover portions of the first and second flexible regions 211 and 212, such that both sides of the first etching stop pattern 133 may be positioned on the first insulating layer 120. Here, a portion at which the first etching stop pattern 133 and the first insulating layer 120 are overlapped with each other may become a cut region 230.

In addition, a first via 191 may be formed in at least one of the first to third rigid regions 221 to 223. In a preferred embodiment of the present invention, the first via 191 may be formed in the first rigid region 221 and the second rigid region 222.

According to a preferred embodiment of the present invention, the first via 191 may be formed. The first via 191 may penetrate through the first insulating layer 120 and the first build-up insulating layer 131 to electrically connect the internal circuit pattern 112 and the first circuit pattern 132 to each other.

In addition, a first penetration via 195 may be formed in the first rigid region 221. In a preferred embodiment of the present invention, the first penetration via 195 may be formed so that the first circuit patterns 132 formed above and below the flexible substrate 110, respectively, are electrically connected to each other.

In a preferred embodiment of the present invention, the first via 191 and the first penetration via 195 may be omitted by selection of those skilled in the art.

According to a preferred embodiment of the present invention, the first build-up insulating layer 131, the first circuit patter 132, and the first etching stop pattern 133 may configure the first build-up layer 130.

The first build-up layer 130, the first via 191, and the first penetration via 195 according to a preferred embodiment of the present invention may be formed by methods of forming a circuit pattern, an insulating layer, a blind via, and a penetration via that are applied in a field of circuit board. In addition, although the case in which the first build-up layer 130 includes one insulating layer and the circuit pattern has been described in a preferred embodiment of the present invention, the present invention is not limited thereto. That is, the first build-up layer 130 may include a plurality of insulating layers and the circuit pattern depending on selection of those skilled in the art.

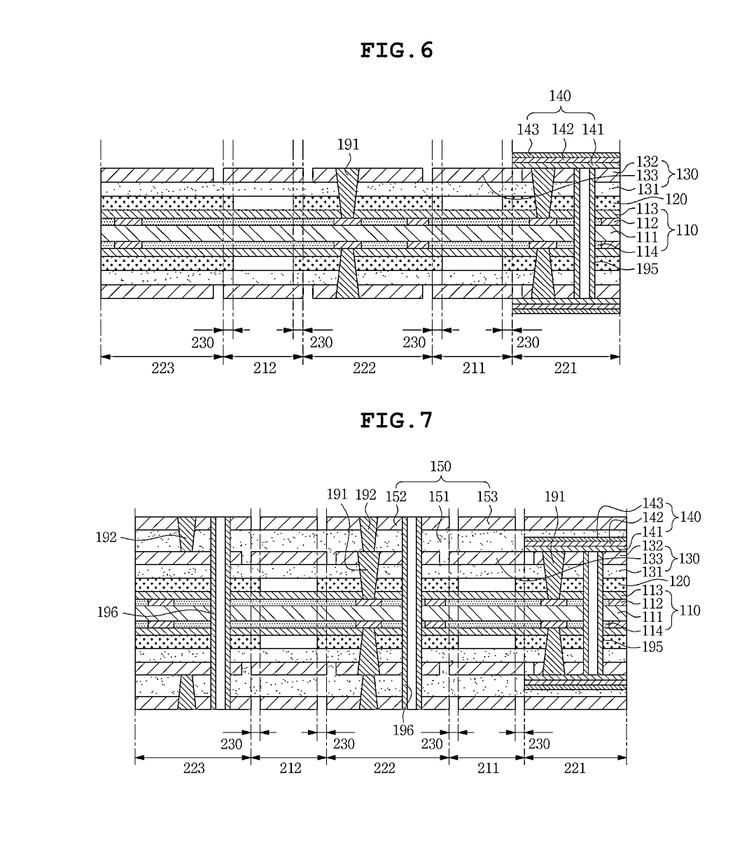

Referring to FIG. 6, a first boundary layer 140 may be formed.

According to a preferred embodiment of the present invention, the first boundary layer 140 may be formed on the first circuit pattern 132 of the first rigid region 221. The first boundary layer 140 may be formed in order to distinguish between the outermost layer of the first rigid region 221 and a region that is removed. That is, the outermost layer of the first rigid region 221 may become the first circuit pattern 132 later.

According to a preferred embodiment of the present invention, the first boundary layer 140 may include a first protective layer 141, a first adhesive layer 142, and a first release layer 143. For example, the first boundary layer 140 may be formed of a coverlay. The first adhesive layer 142 may be positioned between the first protective layer 141 and the first release layer 143. In a preferred embodiment of the present invention, when the first boundary layer 140 is formed in the first rigid region 221, the first protective layer 141 may be positioned on an upper surface of the first circuit pattern 132. Here, the first adhesive layer 142 may be formed of a material that has low adhesion and may be separated from the first protective layer 141 by a physical or mechanical method.

Although the case in which the first boundary layer 140 is formed in a three-layer structure has been described by way of example in a preferred embodiment of the present invention, the present invention is not limited thereto. For example, the first boundary layer 140 may have a two-layer structure including the first protective layer 141 and the first release layer 143. Here, the first release layer 143 may have low adhesion. Therefore, the first release layer 143 may be separated from the first protective layer 141 by a mechanical or physical method.

Referring to FIG. 7, a second build-up layer 150 may be formed.

The second build-up layer 150 according to a preferred embodiment of the present invention may include a second build-up insulating layer 151, a second circuit pattern 152, and a second etching stop pattern 153.

According to a preferred embodiment of the present invention, the second build-up insulating layer 151 may be formed on the first build-up layer 130 and the first boundary layer 140.

The second circuit pattern 152 may be formed on the second build-up insulating layer 151. In a preferred embodiment of the present invention, the second circuit pattern 152 may be formed in the first to third rigid regions 221 to 223. Here, the second circuit pattern 152 formed in the second and third rigid regions 222 and 223 may be a circuit pattern for transmitting a signal. In addition, the second circuit pattern 152 formed in the first rigid region 221 may be a dummy pattern. In a preferred embodiment of the present invention, the second build-up insulating layer 151 formed in the first rigid region 221 and the second circuit pattern 152 formed in the first rigid region 221 and corresponding to the dummy pattern may be removed later.

The second etching stop pattern 153 may be formed on the second build-up insulating layer 151 formed in the first and second flexible regions 211 and 212. Here, the second etching stop pattern 153 may be formed so that the second build-up insulating layer 151 formed in a cut region 230 is exposed.

According to a preferred embodiment of the present invention, a second via 192 may be formed. The second via 192 may penetrate through the second build-up insulating layer 151 to electrically connect the first circuit pattern 132 and the second circuit pattern 152 to each other.

According to a preferred embodiment of the present invention, a second penetration via 196 may be formed. The second penetration via 196 may electrically connect the second circuit patterns 152 formed above and below the flexible substrate 110, respectively, to each other.

According to a preferred embodiment of the present invention, the second build-up layer 150 may be formed by a method of forming the first build-up layer 130. In addition, the second via 192 and the second penetration via 196 may also be formed by a method of forming the first via 191 and the first penetration via 195. In addition, although the case in which the second build-up layer 150 includes one insulating layer and the circuit pattern has been described in a preferred embodiment of the present invention, the present invention is not limited thereto. That is, the second build-up layer 150 may include a plurality of insulating layers and the circuit pattern depending on selection of those skilled in the art.

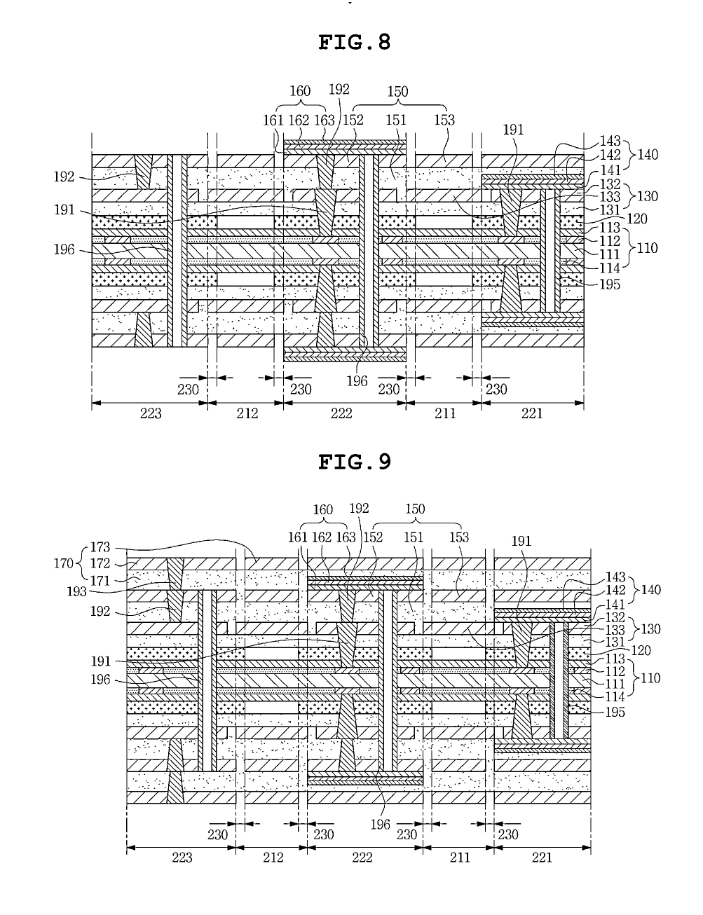

Referring to FIG. 8, a second boundary layer 160 may be formed.

According to a preferred embodiment of the present invention, the second boundary layer 160 may be formed on the second circuit pattern 152 of the second rigid region 222. The second boundary layer 160 may be formed in order to distinguish between the outermost layer of the second rigid region 222 and a region that is removed. That is, the outermost layer of the second rigid region 222 may become the second circuit pattern 152 later.

According to a preferred embodiment of the present invention, the second boundary layer 160 may include a second protective layer 161, a second adhesive layer 162, and a second release layer 163. For example, the second boundary layer 160 may be formed of a coverlay. The second adhesive layer 162 may be positioned between the second protective layer 161 and the second release layer 163. Here, the second adhesive layer 162 may have low adhesion. Therefore, the second adhesive layer 162 may be separated from the second protective layer 161 by a mechanical or physical method. In a preferred embodiment of the present invention, when the second boundary layer 160 is formed in the second rigid region 222, the second protective layer 161 may be positioned on an upper surface of the second circuit pattern 152.

Although the case in which the second boundary layer 160 is formed in a three-layer structure has been described by way of example in a preferred embodiment of the present invention, the present invention is not limited thereto. For example, the second boundary layer 160 may have a two-layer structure including the second protective layer 161 and the second release layer 163. Here, the second release layer 163 may have low adhesion. Therefore, the second release layer 163 may be separated from the second protective layer 161 by a mechanical or physical method.

Referring to FIG. 9, a third build-up layer 170 may be formed.

The third build-up layer 170 according to a preferred embodiment of the present invention may include a third build-up insulating layer 171, a third circuit pattern 172, and a third etching stop pattern 173.

According to a preferred embodiment of the present invention, the third build-up insulating layer 171 may be formed on the second build-up layer 150 and the second boundary layer 160.

The third circuit pattern 172 may be formed on the third build-up insulating layer 171. According to a preferred embodiment of the present invention, the third circuit pattern 172 may be formed in the first to third rigid regions 221 to 223. Here, the third circuit pattern 172 formed in the third rigid region 223 may be a circuit pattern for transmitting a signal. In addition, the third circuit pattern 172 formed in the first and second rigid regions 221 and 222 may be a dummy pattern. In a preferred embodiment of the present invention, the third build-up insulating layer 171 formed in the first and second rigid regions 221 and 222 and the third circuit pattern 172 formed in the first and second rigid regions 221 and 222 and corresponding to the dummy pattern may be removed later.

In a preferred embodiment of the present invention, the third circuit pattern 172 may be formed in the first to third rigid regions 221 to 223.

The third etching stop pattern 173 may be formed on the third build-up insulating layer 171 formed in the first and second flexible regions 211 and 212. Here, the third etching stop pattern 173 may be formed so that the third build-up insulating layer 171 formed in a cut region 230 is exposed.

According to a preferred embodiment of the present invention, a third via 193 may be formed. The third via 193 may penetrate through the third build-up insulating layer 171 to electrically connect the second circuit pattern 152 and the third circuit pattern 172 to each other. The third via 193 may be formed by a method of forming the first via 191 or the second via 192.

According to a preferred embodiment of the present invention, the third build-up layer 170 may be formed by a method of forming the first build-up layer 130 or the second build-up layer 150. In addition, although the case in which the third build-up layer 170 includes one insulating layer and the circuit pattern has been described in a preferred embodiment of the present invention, the present invention is not limited thereto. That is, the third build-up layer 170 may include a plurality of insulating layers and the circuit pattern depending on selection of those skilled in the art.

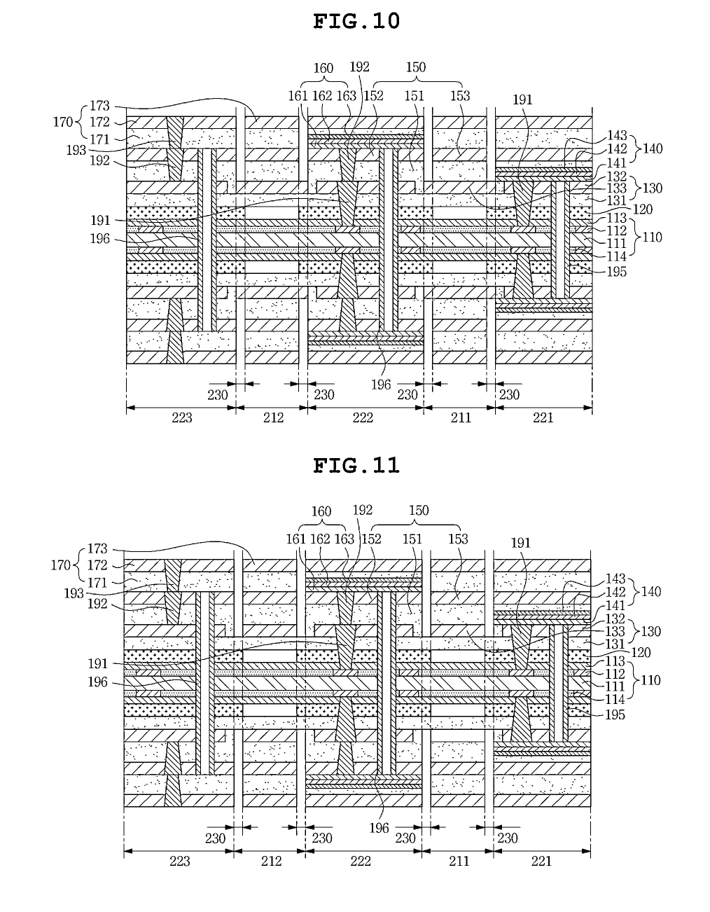

Referring to FIG. 10, the second build-up insulating layer 151 and the third build-up insulating layer 171 of the cut region 230 may be removed.

According to a preferred embodiment of the present invention, the cut region 230 may be removed using a laser drill. According to a preferred embodiment of the present invention, the cut region 230 may be configured of the second build-up insulating layer 151 and the third build-up insulating layer 171. The second build-up insulating layer 151 and the third build-up insulating layer 171 of the cut region 230 may be removed using the laser drill. In this case, regions other than the cut region 230 may be protected by the first to third etching stop pattern 133 to 173.

The first and second flexible regions 211 and 212 may be protected from drilling of the laser drill. In addition, since the first etching stop pattern 133 is also formed in the cut region 230, it may prevent the first insulating layer 120 and the first build-up insulating layer 131 from being removed by the laser drill. That is, only a cut region 230 on the first etching stop pattern 133 may be removed by the first etching stop pattern 133.

Referring to FIG. 11, the first etching stop pattern 133 of the cut region 230 may be removed.

According to a preferred embodiment of the present invention, when the second build-up insulating layer 151 and the third build-up insulating layer 171 of the cut region 230 are removed, the first etching stop pattern 133 positioned in the cut region 230 may be exposed. The first etching stop patter 133 positioned in the cut region 230 may be removed using an etchant.

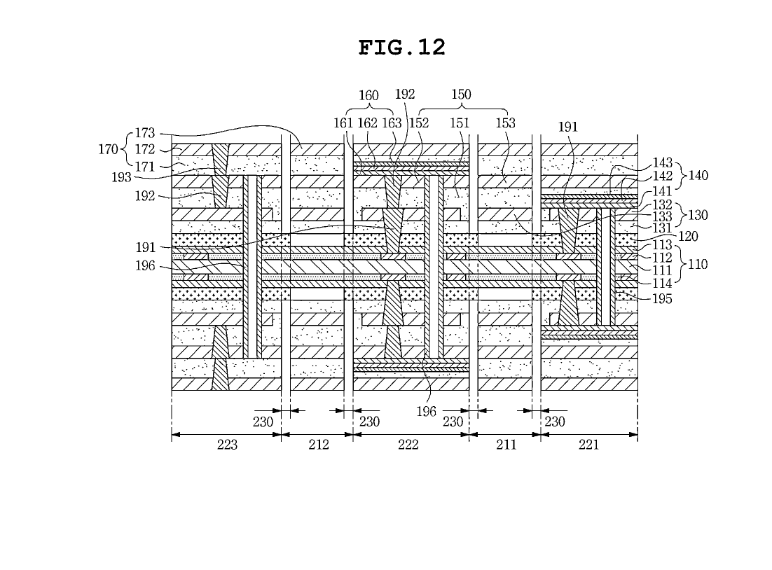

Referring to FIG. 12, the first build-up insulating layer 131 of the cut region 230 may be removed.

According to a preferred embodiment of the present invention, when the first etching stop pattern 133 of the cut region 230 is removed, the first build-up insulating layer 131 positioned in the cut region 230 may be exposed. The first build-up insulating layer 131 of the cut region 230 exposed as described above may be removed using a laser drill. In this case, an output of the laser drill is adjusted, thereby making it possible to prevent the first insulating layer 120 and the internal protective layer 113 of the first and second flexible regions 211 and 212 from being removed.

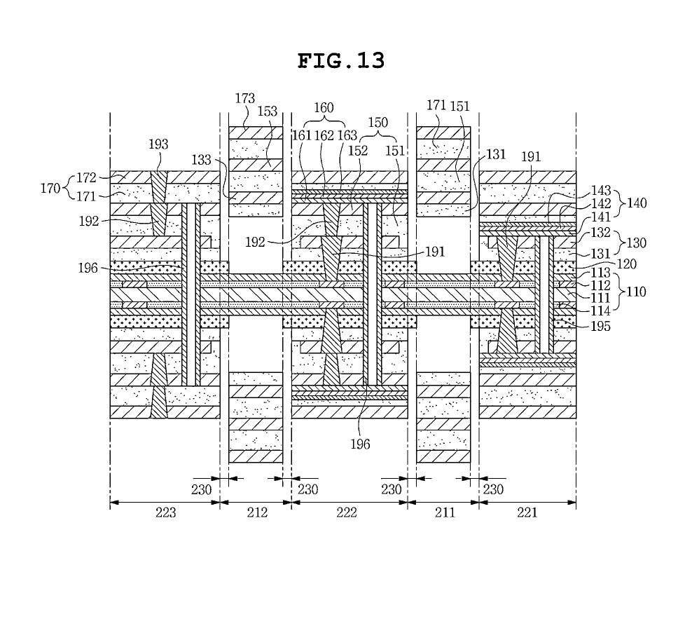

Referring to FIG. 13, the first to third build-up layers 130 to 170 of the first and second flexible regions 211 and 212 may be removed.

According to a preferred embodiment of the present invention, the first to third build-up layers 130 to 170 may be separated and removed from the first insulating layer 120 in the first and second flexible regions 211 and 212 by removing the cut region 230 as described above with reference to FIGS. 10 to 12. That is, the first build-up insulating layer 131, the first etching stop pattern 133, the second build-up insulating layer 151, the second etching stop pattern 153, the third build-up insulating layer 171, and the third etching stop pattern 173 formed in the first and second flexible regions 211 and 212 may be removed.

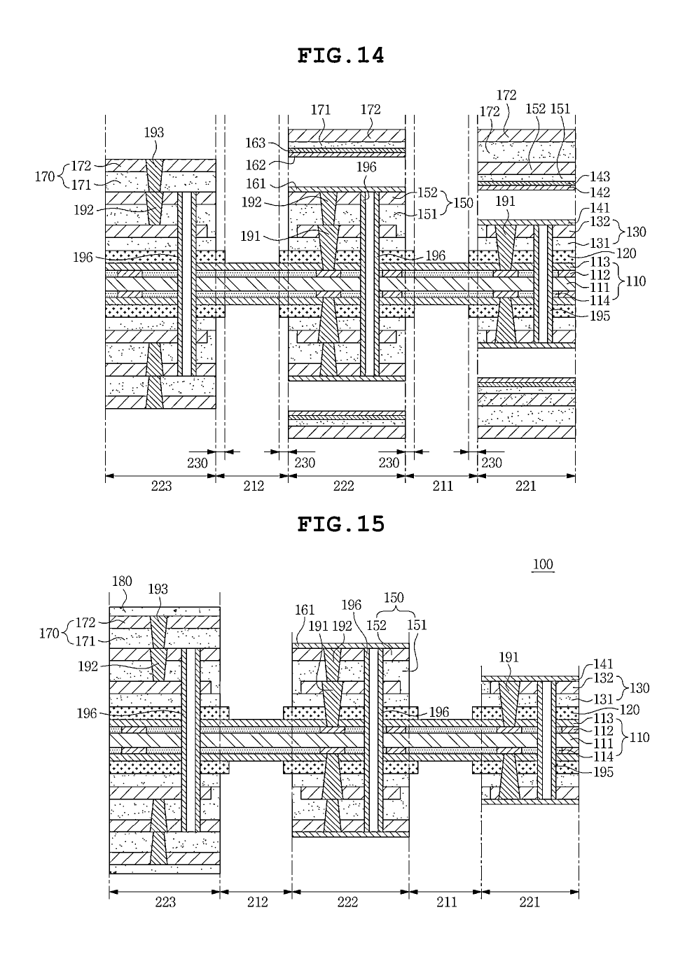

Referring to FIG. 14, an upper portion of the first protective layer 141 of the first rigid region 221 and the second protective layer 161 of the second rigid region 222 may be removed.

According to a preferred embodiment of the present invention, the first protective layer 141 and the first adhesive layer 142 of the first boundary layer 140 are separated from each other, such that the second and third build-up layers 150 and 170 formed in the first rigid region 221 may be removed. In this case, the second build-up layer 150 that is removed may become the second build-up insulating layer 151 and the second circuit pattern 152. In addition, the third build-up layer 170 that is removed together with the second build-up layer 150 may become the third build-up insulating layer 171 and the third circuit pattern 173. Here, the second and third circuit patterns 152 and 153 may be a dummy pattern. Therefore, according to a preferred embodiment of the present invention, the outermost layer of the first rigid region 221 may become the first circuit pattern 132 and the first protective layer 141 of the first build-up layer 130.

In addition, the second protective layer 161 and the second adhesive layer 162 of the second boundary layer 160 are separated from each other, such that the third build-up layer 170 may be removed. In this case, the third build-up layer 170 that is removed may become the third build-up insulating layer 171 and the third circuit pattern 173. Here, the third circuit pattern 153 may be a dummy pattern. Therefore, according to a preferred embodiment of the present invention, the outermost layer of the second rigid region 222 may become the second circuit pattern 152 and the second protective layer 161 of the second build-up layer 150.

In addition, the outermost layer of the third rigid region 223 may become the third circuit pattern 172 of the third build-up layer 170.

The build-up layers having different numbers are different from each other may be simultaneously formed in the first to third rigid regions 221 to 223 using the first and second boundary layers 140 and 160 according to a preferred embodiment of the present invention as described above. That is, according to a preferred embodiment of the present invention, the respective rigid regions may have different thicknesses. According to the prior art, since an insulating layer was punched and then stacked and a circuit pattern was formed, an internal protective layer of a flexible region was damaged by a liquid process such as an etching process, a desmear process, and the like. However, according to a preferred embodiment of the present invention, the internal protective layer of the flexible region may be exposed after a plating process, an etching process, and the like, are completed. Therefore, it is possible to prevent the internal protective layer from being damaged by the liquid process according to the prior art.

Referring to FIG. 15, an external protective layer 180 may be formed.

According to a preferred embodiment of the present invention, the external protective layer 180 may be formed on the third circuit pattern 172 of the third rigid region 223. The external protective layer 180 may be formed in order to protect the third circuit pattern 172 from an external environment or material such as a solder, or the like. For example, the external protective layer 180 may be formed of a liquid or film type of solder resist. Alternatively, the external protective layer 180 may be formed of a coverlay. However, the external protective layer 180 is not limited to being formed of the above-mentioned material, may be formed of a material selected among multiple materials protecting a circuit pattern in a field of circuit board. In addition, a method of forming the external protective layer 180 may be changed depending on the selected material.

In a preferred embodiment of the present invention, since the first and second protective layers 141 and 161 are formed on the outermost layers of the first and second rigid regions 221 and 222, respectively, the external protective layer 180 may be omitted in the first and second rigid regions 221 and 222. However, the external protective layer 180 may also be formed in the first and second rigid regions 221 and 222 by those skilled in the art, if necessary. For example, the first and second protective layers 141 and 161 of the first and second rigid regions 221 and 222 may be removed, and the external protective layer 180 may be formed on the first and second circuit patterns 132 and 152. Alternatively, the external protective layer 180 may be formed on the first and second protective layers 141 and 161 of the first and second rigid regions 221 and 222.

In a preferred embodiment of the present invention, a process of forming the external protective layer 180 is performed after an unnecessary region is removed, but is not limited thereto. That is, the process of forming the external protective layer 180 may be performed in any sequence after the third build-up layer 170 is formed.

With the method of manufacturing a rigid flexible printed circuit board according to a preferred embodiment of the present invention as described above, the rigid flexible printed circuit board 100 in which the build-up layers having different numbers and thicknesses are formed in the respective rigid regions may be formed.

With the rigid flexible printed circuit board and the method of manufacturing the same according to a preferred embodiment of the present invention, the build-up layers having various numbers may be simultaneously formed.

With the rigid flexible printed circuit board and the method of manufacturing the same according to a preferred embodiment of the present invention, it is possible to prevent the internal protective layer exposed in the flexible region from being damaged by the liquid process.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A rigid flexible printed circuit board comprising:
a flexible substrate having a flexible region and a plurality of rigid regions;
a first insulating layer formed in the rigid regions and extended from the rigid regions to cover a portion of the flexible region; and
a plurality of build-up layers formed in the first insulating layer of the rigid regions and including a build-up insulating layer and a circuit pattern,
wherein at least one of the plurality of build-up layers has a thickness different from those of the other build-up layers.

2. The rigid flexible printed circuit board as set forth in claim 1, further comprising protective layers formed on the build-up layers.

3. The rigid flexible printed circuit board as set forth in claim 2, wherein the protective layer is formed of a solder resist or a coverlay.

4. The rigid flexible printed circuit board as set forth in claim 2, wherein a protective layer of a build-up layer having the thickest thickness among the plurality of build-up layers is formed of a solder resist, and protective layers of the other build-up layers are formed of a coverlay.

5. The rigid flexible printed circuit board as set forth in claim 1, wherein the first insulating layer and the build-up layer are formed on both surfaces of the flexible substrate.

6. The rigid flexible printed circuit board as set forth in claim 1, wherein the flexible substrate includes a flexible insulating layer, an internal circuit pattern formed on one surface or both surfaces of the flexible insulating layer, and an internal protective layer formed on the internal circuit pattern.

7. The rigid flexible printed circuit board as set forth in claim 6, wherein the internal protective layer is formed of a coverlay.

8. A method of manufacturing a rigid flexible printed circuit board, comprising:
preparing a flexible substrate having a flexible region and a plurality of rigid regions;
forming a first insulating layer in the rigid regions so as to be extended from the rigid regions to cover a portion of the flexible region;
forming a first build-up layer at an upper portion of the flexible region and on the first insulating layer, the first build-up layer including a first build-up insulating layer and a first circuit pattern;
forming a boundary layer on a first build-up layer of at least one of the plurality of rigid regions;
forming a second build-up layer on the first build-up layer and the boundary layer, the second build-up layer including a second build-up insulating layer and a second circuit pattern;
removing the first build-up layer and the second build-up layer of the flexible region; and
removing the second build-up layer formed on the boundary layer.

9. The method of manufacturing a rigid flexible printed circuit board as set forth in claim 8, wherein the forming of the first build-up layer further includes forming an etching stop pattern in the flexible region.

10. The method of manufacturing a rigid flexible printed circuit board as set forth in claim 9, wherein the etching stop pattern is formed simultaneously with the first circuit pattern.

11. The method of manufacturing a rigid flexible printed circuit board as set forth in claim 9, wherein the removing of the first build-up layer and the second build-up layer includes:
removing the first build-up layer and the second build-up layer formed on the first insulating layer formed in the flexible region using a laser drill;
wet-etching the etching stop pattern exposed by removing the first build-up layer and the second build-up layer;
removing the first build-up insulating layer by wet-etching the etching stop pattern using the laser drill; and
separating and removing the first build-up insulating layer, the etching stop pattern, and the first build-up layer, and the second build-up layer formed at the upper portion of the flexible region.

12. The method of manufacturing a rigid flexible printed circuit board as set forth in claim 8, wherein in the forming of the boundary layer, the boundary layer includes a protective layer positioned on an upper surface of the first build-up layer and a release layer formed on the protective layer.

13. The method of manufacturing a rigid flexible printed circuit board as set forth in claim 12, wherein the protective layer is formed of a coverlay.

14. The method of manufacturing a rigid flexible printed circuit board as set forth in claim 12, wherein in the removing of the second build-up layer formed on the boundary layer, the protective layer and the release layer of the boundary layer are separated from each other, such that the release layer and the second build-up layer are removed.

15. The method of manufacturing a rigid flexible printed circuit board as set forth in claim 14, wherein in the forming of the boundary layer, the boundary layer further includes an adhesive layer interposed between the protective layer and the release layer, and
in the removing of the second build-up layer formed on the boundary layer, the protective layer and the adhesive layer of the boundary layer are separated from each other, such that the adhesive layer, the release layer, and the second build-up layer are removed.

16. The method of manufacturing a rigid flexible printed circuit board as set forth in claim 8, further comprising, after the forming of the second build-up layer or after the removing of the second build-up layer formed on the boundary layer, forming an external protective layer on the second build-up layer of the rigid region.

17. The method of manufacturing a rigid flexible printed circuit board as set forth in claim 16, wherein in the forming of the external protective layer, the external protective layer is formed of solder ink or a coverlay.

18. The method of manufacturing a rigid flexible printed circuit board as set forth in claim 8, wherein in the forming of the first insulating layer, the first insulating layer is formed on both surfaces of the flexible substrate.

19. The method of manufacturing a rigid flexible printed circuit board as set forth in claim 8, wherein the flexible substrate includes a flexible insulating layer, an internal circuit pattern formed on one surface or both surfaces of the flexible insulating layer, and an internal protective layer formed on the internal circuit pattern.

20. The method of manufacturing a rigid flexible printed circuit board as set forth in claim 19, wherein the internal protective layer is formed of a coverlay.
